(19) United States
(12) Patent Application Publication
(10) Pub. No.: US 2024/0301129 A1
(43) Pub. Date: Sep. 12, 2024

(54) LIQUID MOLD COMPOUNDS, REACTION PRODUCTS OF WHICH BECOME PLATABLE UPON EXPOSURE TO LASER ENERGY

(71) Applicant: Henkel AG & Co. KGaA, Duesseldorf (DE)

(72) Inventors: Chunlin He, Irvine, CA (US); Timothy M. Champagne, Anaheim, CA (US); Jay Chao, Irvine, CA (US); Ruud de Wit, Nieuwegein (NL)

(21) Appl. No.: 18/667,102

(22) Filed: May 17, 2024

Related U.S. Application Data
(63) Continuation of application No. PCT/US2022/050259, filed on Nov. 17, 2022.
(60) Provisional application No. 63/280,512, filed on Nov. 17, 2021.

(51) Int. Cl. C08G 59/24; C08G 59/22; C08G 59/32; C08G 59/50; C08K 3/22; C08K 3/36; H01L 21/56; H01L 23/29

(52) U.S. Cl. CPC C08G 59/245; C08G 59/226; C08G 59/3227; C08G 59/50; C08K 3/22; C08K 3/36; H01L 21/56; H01L 23/295; H01L 2924/3511

(57) ABSTRACT

Thermosetting resin compositions in a flowable state useful for liquid compression molding (“LCM”) or stencil printing application are provided, reaction products of which become non-flowable after exposure to an elevated temperature and are then platable upon exposure to laser energy.

### BACKGROUND

### Field

Thermosetting resin compositions in a flowable state useful for liquid compression molding (“LCM”) or stencil printing application are provided, reaction products of which become non-flowable after exposure to an elevated temperature and are then platable upon exposure to laser energy.

### Brief Description of Related Technology

As semiconductor packaging continues to evolve, requirements for material encapsulation are changing. To protect electronic parts, such as semiconductor devices, a conventional method is to use transfer molding by applying solid epoxy resin compositions. However, with semiconductor devices getting thinner and more densely packed, the method is limited due to flowing defects occurring near the fine openings, and potential damage to some delicate parts.

Therefore, LCM or stencil printing was developed as a processing technique to help protect electronic devices. Compared to transfer molding, LCM or stencil printing is advantageous, in that resin flows more readily into narrow gaps and there is less likelihood of damaging the electronic parts. Many semiconductor wafer-level packages (“WLP”) already used LCM to encapsulate thin and delicate devices.

However, there are many issues for LCM or stencil printing to meet the need for commercial volumes and the reliability needed in the semiconductor packaging industry, particularly for WLP.

Warpage is a common problem seen with many cured LCM or liquid encapsulants. This is particularly prevalent when packaging size is increasing and thickness of the wafers is continuously decreasing. With these contrasting demands, the warpage problem could become too severe to meet the processing requirements, potentially leading to semiconductor packaging failure.

To address the warpage issue, many LCM or liquid encapsulants have been formulated to reduce modulus and glass transition temperatures (“Tg”). However, when proceeding down this path, the encapsulated packages have less of a chance to pass reliability testing.

Conventional materials used to form the molded wafer have either not possessed the desired physical properties to offer improved resistance to wafer warpage, or have not lent themselves to application by LCM processing techniques.

In the past, attempts have been made to address the warpage issue. For instance, U.S. Pat. No. 9,263,360 is directed to and claims a thermosetting resin composition, comprising a thermosetting resin matrix comprising the combination of an epoxy resin component, and an epoxy curing agent consisting of a phenolic novolac component, optionally an additional component selected from an episulfide resin, an oxazine, an oxazoline, a cyanate ester, a maleimide, a nadimide, an itaconimide, and combinations thereof; a block copolymer, a silica filler and optionally a catalyst and accelerator. Here, the block copolymer is an amphiphilic one selected from copolymers made from polystyrene, 1,4-polybutadiene and syndiotactic poly(methyl methacrylate); polymethylmethacrylate-block-polybutylacrylate-block polymethylmethacrylate copolymers; and combinations thereof. The silica filler comprises 50 to 90 percent by weight of the composition.

And U.S. Pat. No. 8,847,415 is directed to and claims a liquid compression molding curable resin composition, comprising a curable resin matrix, a cure component comprising a cationic catalyst and an oxidant. When cured, the composition exhibits a DSC peak below 140° C. and a delta temperature between the onset temperature and the peak on DSC below 20° C.

U.S. Pat. No. 9,263,360 provides a thermosetting resin composition, comprising a thermosetting resin matrix, a block copolymer, a silica filler and a cure component comprising the combination of an anhydride or a phenolic resin and an imidazole. When cured the composition exhibits a modulus in the range of about 22 GPas or less at room temperature, a CTE al of less than or equal to 10 um/° C., and multiple Tgs that include for instance a T_{g1} of about −70° C. to −30° C. and a T_{g2} of about 100° C. to 150° C.

Similarly, U.S. Pat. No. 6,727,325 is directed to and claims an epoxy resin composition, comprising an epoxy resin prior to curing, and a clathrate comprising a tetrakisphenol compound represented by a specified formula and a compound that can react with the epoxy resin to cure the resin.

And International Patent Publication No. WO 2020/037199 describes a thermosetting resin composition, comprising a thermosetting resin matrix, a silica filler, and a curing component, the curing component comprising a combination of a clathrate comprising the combination of a tetrakisphenol compound and a nitrogen-containing curative, where the composition has an increase in viscosity of less than about 30%, after storage at room temperature for 24 hours and where the composition exhibits less than about 3 cm warping after oven curing when the composition is cured on a wafer.

Now, the industry is trending toward integrating electrical circuitry directly into or onto a molded package, the molded package having dielectric properties.

For instance, U.S. Pat. No. 7,547,849 (Lee) is directed to a laser light-activatable, platable, self-supporting composite film comprising:
A. a polymer binder selected from epoxy resins, silica filled epoxy, bismaleimide resins, bismaleimide triazines, fluoropolymers, polyesters, polyphenylene oxide/polyphenylene ether resins, polybutadiene/polyisoprene crosslinkable resins (and copolymers), liquid crystal polymers, polyamides, cyanate esters, and combinations thereof, the polymer binder being present in an amount from 50 to 97 weight percent of the total weight of the composite film; and
B. a spinel crystal filler present in an amount from 3 to 50 weight percent of the total weight of the polymer composite film; and
   wherein:
the polymer composite has a 400 nm to 1,000,000 nm light extinction coefficient from 0.05 to 0.6 per micron, the spinel crystal filler is represented by a chemical formula AB₂O₄ or BABO₄, where A is a metal cation having a valence of 2 selected from cadmium, zinc, copper, cobalt, magnesium, tin, titanium, iron, aluminum, nickel, manganese, chromium, and combinations of two or more of these, and where B is a metal cation having a valence of 3 selected from cadmium, manganese, nickel, copper, cobalt, iron, tin, titanium, aluminum, chromium, and combinations of two or more of these, and
the film is a self-supporting film.

Moreover, U.S. Patent Application Publication No. 2019/0292386 (Meura) is directed to a thermosetting resin composition for laser direct structuring (LDS), comprising a thermosetting resin; an inorganic filler; a non-conductive metal compound that forms a metal nucleus upon irradiation with active energy rays; and a coupling agent, wherein the non-conductive metal compound includes one or more selected from the group consisting of a spinel-type metal oxide, a metal oxide having two or more transition metal elements in groups adjacent to each other, the groups being selected from groups 3 to 12 of the periodic table, and a tin-containing oxide, and the coupling agent includes one or more selected from mercaptosilane, aminosilane, and epoxysilane.

Despite these recent efforts, it would be desirable to provide fresh LCM or stencil printing materials, particularly ones which are flowable, laser-activatable, and platable, while providing improved resistance to wafer warpage, thereby giving the end user multiple choices and sources of solutions to the recurring problem of wafer warpage.

And existing technologies could use improvement in the ability to form thinner layers of dielectric during molding, thereby permitting increases in the functional density of the package and removing constraints in package design.

### SUMMARY

The present disclosure provides solutions to these issues and satisfies the market demands in that regard.

Provided herein are thermosetting resin compositions that are capable of curing by exposure to elevated temperature conditions. Once cured, the cured compositions are laser-activated and become platable. In this regard, plating is the basis for laser direct structuring (“LDS”) to produce a three-dimensional molded interconnect device (“MID”). Here, with LDS, spinel crystals are available at or near the surface of the cured composition to receive laser energy applied thereto. (The surface may also be considered during a through via approach.) After the laser energy ablates a predetermined pattern on the surface of the cured composition the spinel crystals may behave as a seed to permit plating, electroless or otherwise, thereby forming a plated pattern in the ablated portion.

And, after the thermosetting resin is cured, the molded substrate resists warpage.

More specifically, the inventive compositions are useful as liquid compression molding encapsulants having low warpage after compression molding and oven cure, while maintaining the desirable physical properties of a molding compound. The compositions exhibit low storage modulus at room temperature (such as about 25 GPas or less, desirably within the range of about 10 to about 20 GPas, such as about 5 to about 9 GPas, at room temperature), and low coefficients of thermal expansion (“CTEs”) (α1<20 ppm; α2<40 ppm).

Cured reaction products of the inventive compositions are capable of improving warpage resistance of the molded substrate by about 50 percent, desirably at least about 65 percent, and even more desirably at least about 80 percent, as compared with a molded substrate with a material other than that which is disclosed herein. The substrate oftentimes is a wafer, constructed of silicon, and the composition is disposed on the wafer at a thickness of less than about 50 percent of the thickness of the wafer, such as at a thickness of less than about 33 percent of the thickness of the wafer.

That is, and importantly, the compositions demonstrate a warpage of less than about 3 cm (such as less than about 2 cm) after curing under liquid compressing molding conditions. This physical property combination shows promise in overcoming some of the significant technical hurdles facing the semiconductor packaging industry at present, particularly with respect to liquid encapsulant substrate warpage. Through the use of the inventive compositions not only is warpage resistance improved during cure, but it is also improved during subsequent processing such as LDS.

Thus, provided in one aspect is a thermosetting resin composition, which reaction product includes a thermosetting resin matrix (such as an epoxy resin component), a filler comprising silica, a spinel crystal, and a cure component comprising the combination of (1) a clathrate comprising a tetrakisphenol compound and (2) a nitrogen containing curing agent, such as imidazole and derivatives thereof.

In another aspect, provided is a method of improving warpage resistance to a molded wafer, steps of which include:
Providing a wafer on which is disposed one or more silicon chip (s);
Providing a thermosetting resin composition as so described in contact with the wafer;
Exposing the wafer and the thermosetting resin composition to conditions favorable to allow the thermosetting resin composition to flow about the wafer; and
Thereafter exposing the thermosetting resin composition to conditions favorable to cure to a reaction product of the thermosetting resin composition.

Once cured, the reaction product of the composition may be exposed to laser energy thereby forming residues or fragments of the spinel crystals located at or about the surface of the reaction product, where residues or fragments act as seeds to form wiring or circuitry through plating.

A method for producing a molded electrically interconnected semiconductor device is also provided herein. The method includes steps which comprise:
Providing a wafer;
Dispensing onto at least a portion of a surface of the wafer a thermosetting resin composition in a flowable state at room temperature, as so-disclosed herein;
Exposing the wafer and the thermosetting resin composition to elevated temperature conditions suitable to cure the composition to form a reaction product on the wafer;
Exposing the so-formed reaction product to laser energy in a predetermined pattern to ablate the reaction product in that predetermined pattern and in so doing exposing a residue of the spinel crystal; and
Performing a plating over the predetermined pattern ablated in the cured reaction product.

In some embodiments the method may include:
Dispensing onto at least a portion of a surface of the reaction product of the cured thermosetting resin composition a further portion of the thermosetting resin composition; Exposing the further portion of thermosetting resin composition to elevated temperature conditions suitable to cure the composition to form a reaction product;
Exposing the so-formed reaction product to laser energy in a predetermined pattern to ablate the reaction product in that predetermined pattern and in so doing exposing a residue of the spinel crystal; and
Performing a plating over the predetermined pattern ablated in the cured reaction product.

The method may be repeated multiple times to build a three dimensional molded electrically interconnected semiconductor device, according to a predetermined pattern.

Of course, a molded electrically interconnected semiconductor device is also provided. This device includes a wafer onto and/or about which is disposed an inventive thermosetting resin composition having been cured to a reaction product through exposure to elevated temperature conditions and having been exposed to laser energy in a predetermined pattern and having formed on that predetermined pattern metallization through plating.

### BRIEF DESCRIPTION OF THE FIGURES

FIG. 1 depicts a process flow diagram of a liquid compression molding encapsulation process for a wafer level packaging application.

FIG. 2 depicts a process flow diagram of a stencil printing encapsulation process for a wafer level packaging application.

FIG. 3 depicts a process flow diagram of the laser-ablating and plating process of cured materials.

### DETAILED DESCRIPTION

The thermosetting resin compositions as noted above, include among other constituents a thermosetting resin matrix (such as an epoxy resin).

Examples of the epoxy resin include epoxies made from bisphenol A, bisphenol F, bisphenol S, bisphenol E, biphenyl or combinations thereof. In addition, two or more different bisphenol epoxies (or hydrogenated versus thereof) within the same type of resin (such as A, F, S or E) may be used.

Commercially available examples of the bisphenol epoxies desirable for use herein include bisphenol-F epoxies [such as RE-404-S from Nippon Kayaku, Japan, and EPICLON 830, 830S, 830A and 830W from Dai Nippon Ink & Chemicals, Inc., and RSL 1738 and YL-983U from Resolution] and bisphenol-A epoxies (such as YL-979 and 980 from Resolution).

The bisphenol epoxies available commercially from Dai Nippon and noted above are promoted as liquid undiluted epichlorohydrin-bisphenol F epoxies having lower viscosities than conventional epoxies based on bisphenol A epoxies and have physical properties similar to liquid bisphenol A epoxies. Bisphenol F epoxy has a lower viscosity than bisphenol A epoxy, all else being the same between the two types of epoxies, which affords a lower viscosity and thus a fast flow underfill sealant material. The EEW of these four bisphenol F epoxies is between 165 and 180. The viscosity at 25° C. is between 3,000 and 4, 500 cps (except for RE1801 whose upper viscosity limit is 4,000 cps). The bisphenol A epoxies have an EEW (g/eq) of between 180 and 195 and a viscosity at 25° C. of between 100 and 250 cps.

The bisphenol epoxies available commercially from Resolution and noted above are promoted as low chloride containing liquid epoxies. The total chloride content for the RSL-1738 bisphenol A epoxy is reported as between 500 and 700 ppm, and that for YL-983U as between 150 and 350 ppm.

Among the epoxies suitable for use herein also include polyglycidyl derivatives of phenolic compounds, such as those available commercially under the tradename EPON, such as EPON 828, EPON 1001, EPON 1009, and EPON 1031 from Resolution; DER 331, DER 332, DER 334, and DER 542 from Dow Chemical Co.; and BREN-S from Nippon Kayaku. Other suitable epoxies include polyepoxides prepared from polyols and the like and polyglycidyl derivatives of phenol-formaldehyde novolacs, the latter of such as DEN 431, DEN 438, and DEN 439 from Dow Chemical. Cresol analogs are also available commercially under the tradename ARALDITE, such as ARALDITE ECN 1235, ARALDITE ECN 1273, and ARALDITE ECN 1299 from Ciba Specialty Chemicals Corporation. SU-8 is a bisphenol-A-type epoxy novolac available from Resolution. Polyglycidyl adducts of amines, aminoalcohols and polycarboxylic acids are also useful in this invention, commercially available resins of which include GLYAMINE 135, GLYAMINE 125, and GLYAMINE 115 from F.I.C. Corporation; ARALDITE MY-720, ARALDITE 0500, and ARALDITE 0510 from Ciba Specialty Chemicals and PGA-X and PGA-C from the Sherwin-Williams Co.

In addition to the bisphenol epoxies, other epoxy compounds may be included within the epoxy component. For instance, cycloaliphatic epoxies, such as 3,4-epoxycyclohexylmethyl-3,4-epoxycyclohexylcarbonate, or hydrogenated versions of the bisphenol or biphenyl epoxies may be used.

Also, monofunctional, difunctional or multifunctional reactive diluents to adjust the viscosity and/or lower the Tg are also used, such as butyl glycidyl ether, cresyl glycidyl ether, polyethylene glycol glycidyl ether or polypropylene glycol glycidyl ether. Appropriate monofunctional epoxy coreactant diluents for use herein include those that have a viscosity which is lower than that of the epoxy component, ordinarily, less than about 250 cps.

The monofunctional epoxy coreactant diluents should have an epoxy group with an alkyl group of about 6 to about 28 carbon atoms, examples of which include C₆₋₂₈ alkyl glycidyl ethers, C₆₋₂₈ fatty acid glycidyl esters and C₁₀₋₂₈ alkylphenol glycidyl ethers.

In the event such a monofunctional epoxy coreactant diluent is included, the coreactant diluent should be employed in an amount of up to about 5 percent by weight to about 15 percent by weight, such as about 8 percent by weight to about 12 percent by weight, based on the total weight of the thermosetting resin matrix.

The epoxy resin component should be present in the composition in an amount which the range of about 10 percent by weight to about 95 percent by weight, desirably about 20 percent by weight to about 80 percent by weight, such as about 60 percent by weight, based on the total weight of the thermosetting resin matrix.

In addition to the epoxy resin, other reactive components may be included such as an episulfide resin, an oxazine, an oxazoline, a cyanate ester, and/or a maleimide-, a nadimide- or an itaconimide-containing component.

As an episulfide resin, any of these epoxies may be used where the oxirane oxygen atom has been replaced by a sulfur atom.

Oxazines may be embraced by the structure

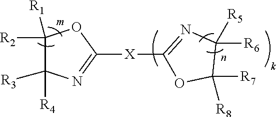

where here R₁-R₈ are each individually members selected from hydrogen, C₁₋₄₀ alkyl, or C₂₋₄₀ alkenyl, the latter two of which being optionally interrupted by one or more of O, N, S, C═O, COO, or NHC═O or substituted by one or more of OH, OR, NRR, SH, SR, COOH, COOR, NHCOOH or NHCOOR, where R is selected from C₁₋₄₀ alkyl, C₂₋₄₀ alkenyl, or C₆₋₂₀ aryl,
X is a linkage selected broadly from alkylene, alkenylene, or arylene, optionally interrupted by one or more of O, NR, S, C═O, COO, or NHC═O or substituted by one or more of OH, OR, NRR, SH, SR, COOH, COOR, NHCOOH or NHCOOR, where R is selected from C₁₋₄₀ alkyl, C₂₋₄₀ alkenyl, or C₆₋₂₀ aryl,
m and n are each individually 1 or 2, and
k is 0 to 6.

When used, the oxazine should be present in the composition in an amount which the range of about 10 percent by weight to about 95 percent by weight, desirably about 20 percent by weight to about 80 percent by weight, such as about 60 percent by weight, based on the total weight of the thermosetting resin matrix.

A more specific example of the oxazine is a benzoxazine, examples of which may be embraced by

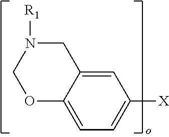

where o is 1-4, X is defined below, and R₁ is alkyl, such as methyl, ethyl, propyls or butyls, or

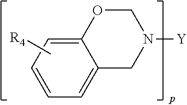

where p is 1-4, Y is defined below, and R₄ is selected from hydrogen, halogen, alkyl or alkenyl.

X and Y in the benzoxazine structures above may independently be selected from a monovalent or polyvalent radical that include
hydrocarbyl or substituted hydrocarbyl species typically having in the range of about 6 up to about 500 carbon atoms, where the hydrocarbyl species is selected from alkyl, alkenyl, alkynyl, cycloalkyl, cycloalkenyl, aryl, alkylaryl, arylalkyl, arylalkenyl, alkenylaryl, arylalkynyl or alkynylaryl, provided, however, that X can be aryl only when X comprises a combination of two or more different species;
hydrocarbylene or substituted hydrocarbylene species typically having in the range of about 6 up to about 500 carbon atoms, where the hydrocarbylene species are selected from alkylene, alkenylene, alkynylene, cycloalkylene, cycloalkenylene, arylene, alkylarylene, arylalkylene, arylalkenylene, alkenylarylene, arylalkynylene or alkynylarylene,
heterocyclic or substituted heterocyclic species typically having in the range of about 6 up to about 500 carbon atoms,
polysiloxane, and
polysiloxane-polyurethane block copolymers, and combinations of one or more of the above with a linker selected from covalent bond, —O—, —S—, —NR—, —NR—C(O)—, —NR—C(O)—O—, —NR—C(O)—NR—, —S—C(O)—, —S—C(O)—O—, —S—C(O)—NR—, —O—S(O)₂—, —O—S(O)₂—O—, —O—S(O)₂—NR—, —O—S(O)—, —O—S(O)—O—, —O—S(O)—NR—, —O—NR—C(O)—, —O—NR—C(O)—O—, —O—NR—C(O)—NR—, —NR—O—C(O)—, —NR—O—C(O)—O—, —NR—O—C(O)—NR—, —O—NR—C(S)—, —O—NR—C(S)—O—, —O—NR—C(S)—NR—, —NR—O—C(S)—, —NR—O—C(S)—O—, —NR—O—C(S)—NR—, —O—C(S)—, —O—C(S)—O—, —O—C(S)—NR—, —NR—C(S)—, —NR—C(S)—O—, —NR—C(S)—NR—, —S—S(O)₂—, —S—S(O)₂—O—, —S—S(O)₂—NR—, —NR—O—S(O)—, —NR—O—S(O)—O—, —NR—O—S(O)—NR—, —NR—O—S(O)₂—, —NR—O—S(O)₂—O—, —NR—O—S(O)₂—NR—, —O—NR—S(O)—, —O—NR—S(O)—O—, —O—NR—S(O)—NR—, —O—NR—S(O)₂—O—, —O—NR—S(O)₂—NR—, —O—NR—S(O)₂—, —O—P(O)R₂—, —S—P(O)R₂—, or —NR—P(O)R₂—; where each R is independently hydrogen, alkyl or substituted alkyl.

When one or more of the above described “X” or “Y” linkages cooperate to form the appendage of a benzoxazine group, as readily recognized by those of skill in the art, a wide variety of organic chains can be produced, such as, for example, oxyalkyl, thioalkyl, aminoalkyl, carboxylalkyl, oxyalkenyl, thioalkenyl, aminoalkenyl, carboxyalkenyl, oxyalkynyl, thioalkynyl, aminoalkynyl, carboxyalkynyl, oxycycloalkyl, thiocycloalkyl, aminocycloalkyl, carboxycycloalkyl, oxycloalkenyl, thiocycloalkenyl, aminocycloalkenyl, carboxycycloalkenyl, heterocyclic, oxyheterocyclic, thioheterocyclic, aminoheterocyclic, carboxyheterocyclic, oxyaryl, thioaryl, aminoaryl, carboxyaryl, heteroaryl, oxyheteroaryl, thioheteroaryl, aminoheteroaryl, carboxyheteroaryl, oxyalkylaryl, thioalkylaryl, aminoalkylaryl, carboxyalkylaryl, oxyarylalkyl, thioarylalkyl, aminoarylalkyl, carboxyarylalkyl, oxyarylalkenyl, thioarylalkenyl, aminoarylalkenyl, carboxyarylalkenyl, oxyalkenylaryl, thioalkenylaryl, aminoalkenylaryl, carboxyalkenylaryl, oxyarylalkynyl, thioarylalkynyl, aminoarylalkynyl, carboxyarylalkynyl, oxyalkynylaryl, thioalkynylaryl, aminoalkynylaryl or carboxyalkynylaryl, oxyalkylene, thioalkylene, aminoalkylene, carboxyalkylene, oxyalkenylene, thioalkenylene, aminoalkenylene, carboxyalkenylene, oxyalkynylene, thioalkynylene, aminoalkynylene, carboxyalkynylene, oxycycloalkylene, thiocycloalkylene, aminocycloalkylene, carboxycycloalkylene, oxycycloalkenylene, thiocycloalkenylene, aminocycloalkenylene, carboxycycloalkenylene, oxyarylene, thioarylene, aminoarylene, carboxyarylene, oxyalkylarylene, thioalkylarylene, aminoalkylarylene, carboxyalkylarylene, oxyarylalkylene, thioarylalkylene, aminoarylalkylene, carboxyarylalkylene, oxyarylalkenylene, thioarylalkenylene, aminoarylalkenylene, carboxyarylalkenylene, oxyalkenylarylene, thioalkenylarylene, aminoalkenylarylene, carboxyalkenylarylene, oxyarylalkynylene, thioarylalkynylene, aminoarylalkynylene, carboxy arylalkynylene, oxyalkynylarylene, thioalkynylarylene, aminoalkynylarylene, carboxyalkynylarylene, heteroarylene, oxyheteroarylene, thioheteroarylene, aminoheteroarylene, carboxyheteroarylene, heteroatom-containing di- or polyvalent cyclic moiety, oxyheteroatom-containing di- or polyvalent cyclic moiety, thioheteroatom-containing di- or polyvalent cyclic moiety, aminoheteroatom-containing di- or polyvalent cyclic moiety, carboxyheteroatom-containing di- or polyvalent cyclic moiety, and the like.

The benzoxazine should be present in the composition in an amount which the range of about 10 percent by weight to about 95 percent by weight, desirably about 20 percent by weight to about 80 percent by weight, such as about 60 percent by weight, based on the total weight of the thermosetting resin matrix.

As a cyanate ester, compounds having the general structural formula below may be used:

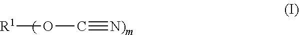

where here m is from 2 to 5 and R¹ is an aromatic nucleus-containing residue. R¹ should contain at least 6 carbon atoms and may be derived, for example, from aromatic hydrocarbons, such as benzene, biphenyl, naphthalene, anthracene, pyrene or the like. The aromatic residue may also be derived from a polynuclear aromatic hydrocarbon in which at least two aromatic rings are attached to each other through a bridging group, such as where the bridging member has the formula

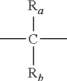

where Rₐ and R_{b} are the same or different and each represents a hydrogen atom or an alkyl group containing 1 to 4 carbon atoms. R¹ also includes residues derived from novolac-type phenolic resins—i.e., cyanate esters of these phenolic resins. R¹ may also contain further ring attached, non-reactive substituents.

Examples of useful cyanate esters include, for instance, 1,3-dicyanatobenzene; 1,4-dicyanatobenzene; 1,3,5-tricyanatobenzene; 1,3-, 1,4-, 1,6-, 1,8-, 2,6- or 2,7-dicyanatonaphthalene; 1,3,6-tricyanatonaphthalene; 4,4′-dicyanato-biphenyl; bis(4-cyanatophenyl) methane and 3,3′,5,5′-tetramethyl, bis(4-cyanatophenyl) methane; 2,2-bis(3,5-dichloro-4-cyanatophenyl) propane; 2,2-bis(3,5-dibromo-4-dicyanatophenyl) propane; bis(4-cyanatophenyl) ether; bis(4-cyanatophenyl) sulfide; 2,2-bis(4-cyanatophenyl) propane; tris(4-cyanatophenyl)-phosphite; tris(4-cyanatophenyl)phosphate; bis(3-chloro-4-cyanatophenyl) methane; cyanated novolac; 1,3-bis [4-cyanatophenyl-1-(methylethylidene)]benzene and cyanated, bisphenol-terminated polycarbonate or other thermoplastic oligomer.

Other cyanate esters include cyanates disclosed in U.S. Pat. Nos. 4,477,629 and 4,528,366, the disclosure of each of which is hereby expressly incorporated herein by reference; the cyanate esters disclosed in U.K. Patent No. 1,305,702, and the cyanate esters disclosed in International Patent Publication No. WO 85/02184, the disclosure of each of which is hereby expressly incorporated herein by reference.

Particularly desirable cyanate esters for use herein are available commercially from Hunstman Advanced Materials, Tarrytown, NY under the tradename AROCY [1,1-di(4-cyanatophenylethane)]. The structures of four desirable AROCY cyanate esters are

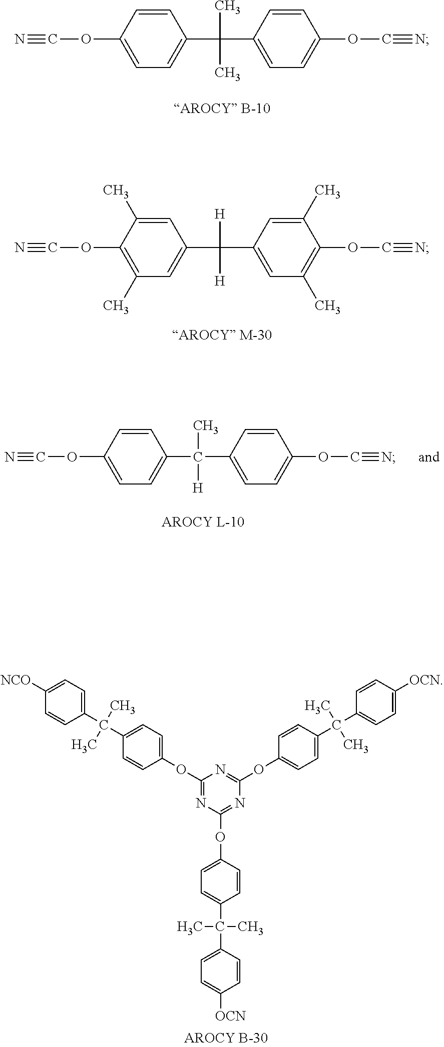

When used, the cyanate ester should be present in an amount which the range of about 10 percent by weight to about 95 percent by weight, desirably about 20 percent by weight to about 80 percent by weight, such as about 60 percent by weight, based on the total weight of the thermosetting resin matrix.

As a maleimide, nadimide or itaconimide, compounds having the general respective structural formulae below may be used:

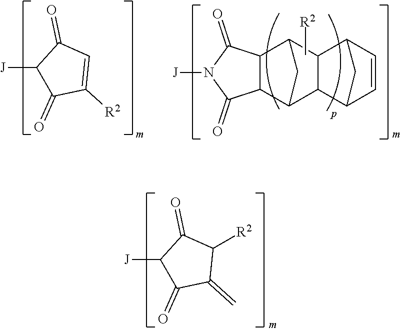

where here m is 1-15, p is 0-15, each R² is independently selected from hydrogen or lower alkyl (such as C₁₋₅), and J is a monovalent or a polyvalent radical comprising organic or organosiloxane radicals, and combinations of two or more thereof, such as are defined as “X” and “Y” with respect to the benzoxazine structure above.

Monovalent or polyvalent radicals include hydrocarbyl or substituted hydrocarbyl species typically having a range of about 6 up to about 500 carbon atoms. The hydrocarbyl species may be alkyl, alkenyl, alkynyl, cycloalkyl, cycloalkenyl, aryl, alkylaryl, arylalkyl, aryalkenyl, alkenylaryl, arylalkynyl and alkynylaryl.

Additionally, X may be a hydrocarbylene or substituted hydrocarbylene species typically having in the range of about 6 up to about 500 carbon atoms. Examples of hydrocarbylene species include but are not limited to alkylene, alkenylene, alkynylene, cycloalkylene, cycloalkenylene, arylene, alkylarylene, arylalkylene, arylalkenylene, alkenylarylene, arylalkynylene and alkynylarylene.

The maleimide, itaconamide or nadimide may be in liquid or solid form.

In a desired embodiment, the maleimide, itaconamide or nadimide functional groups are separated by a polyvalent radical having sufficient length and branching to render the maleimide containing compound a liquid. The maleimide, itaconamide or nadimide compound may contain a spacer between maleimide functional groups comprising a branched chain alkylene between maleimide, itaconamide or nadimide functional groups.

In the case of maleimide-containing compounds, the maleimide compound desirably is a stearyl maleimide, oleyl maleimide, a biphenyl maleimide or a 1,20-bismaleimido-10,11-dioctyl-eixosane or combinations of the above.

Again in the case of maleimide-containing compounds, the maleimide compound may be prepared by reaction of maleic anhydride with dimer amides or prepared from aminopropyl-terminated polydimethyl siloxanes, polyoxypropylene amines, polytetramethyleneoxide-di-p-aminobenzoates, or combinations thereof.

Particularly desirable maleimides and nadimides include

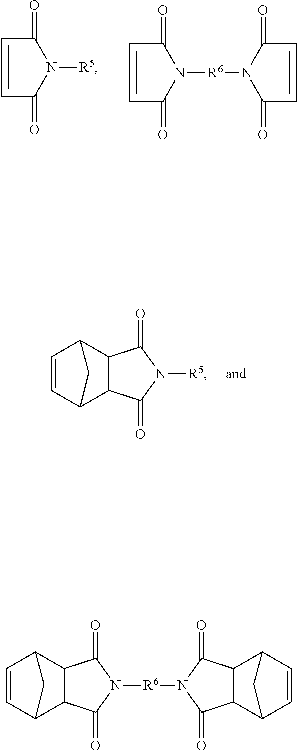

where R₅ and R₆ are each selected from alkyl, aryl, aralkyl or alkaryl groups, having from about 6 to about 100 carbon atoms, with or without substitution or interruption by a member selected from silane, silicon, oxygen, halogen, carbonyl, hydroxyl, ester, carboxylic acid, urea, urethane, carbamate, sulfur, sulfonate and sulfone.

Other desirable maleimides, nadimides, and itaconimides include

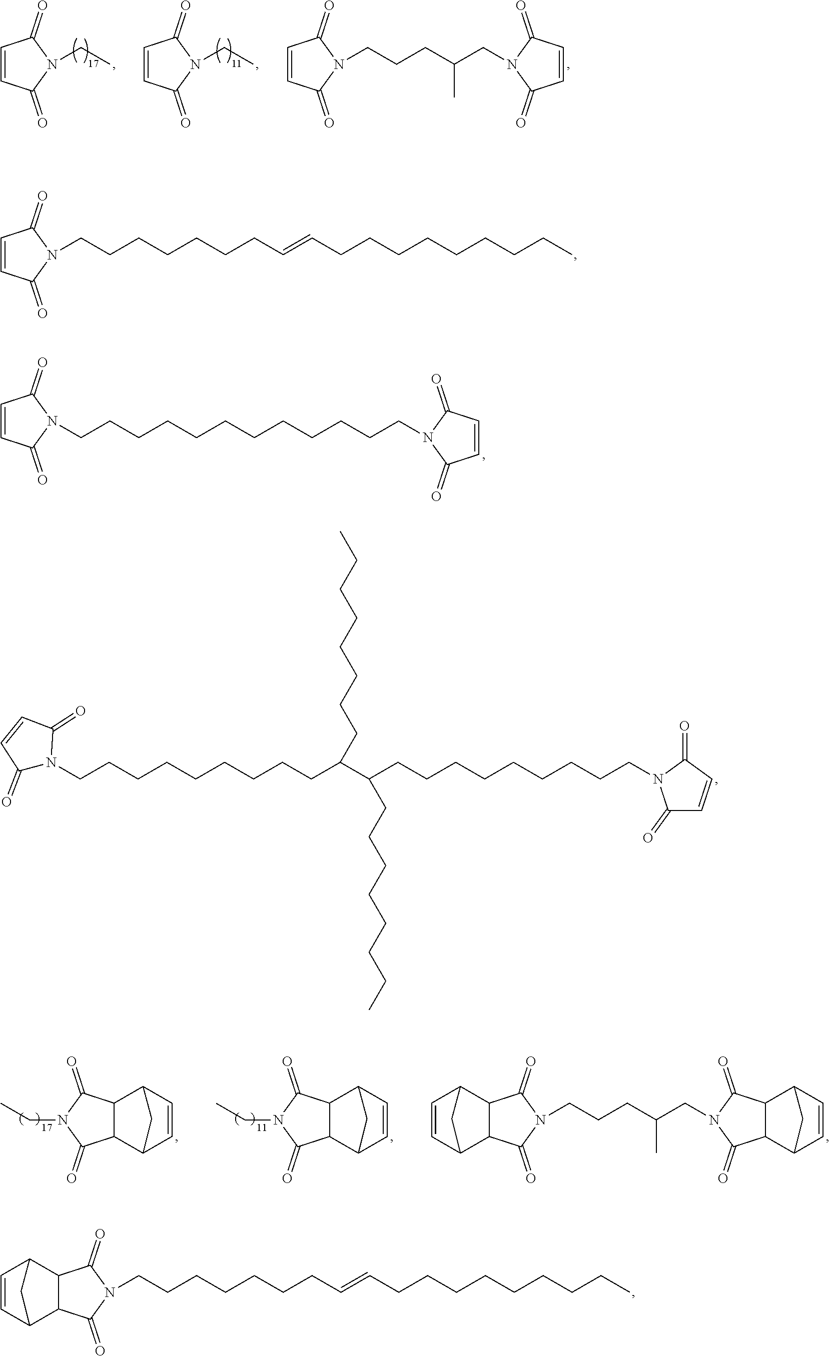

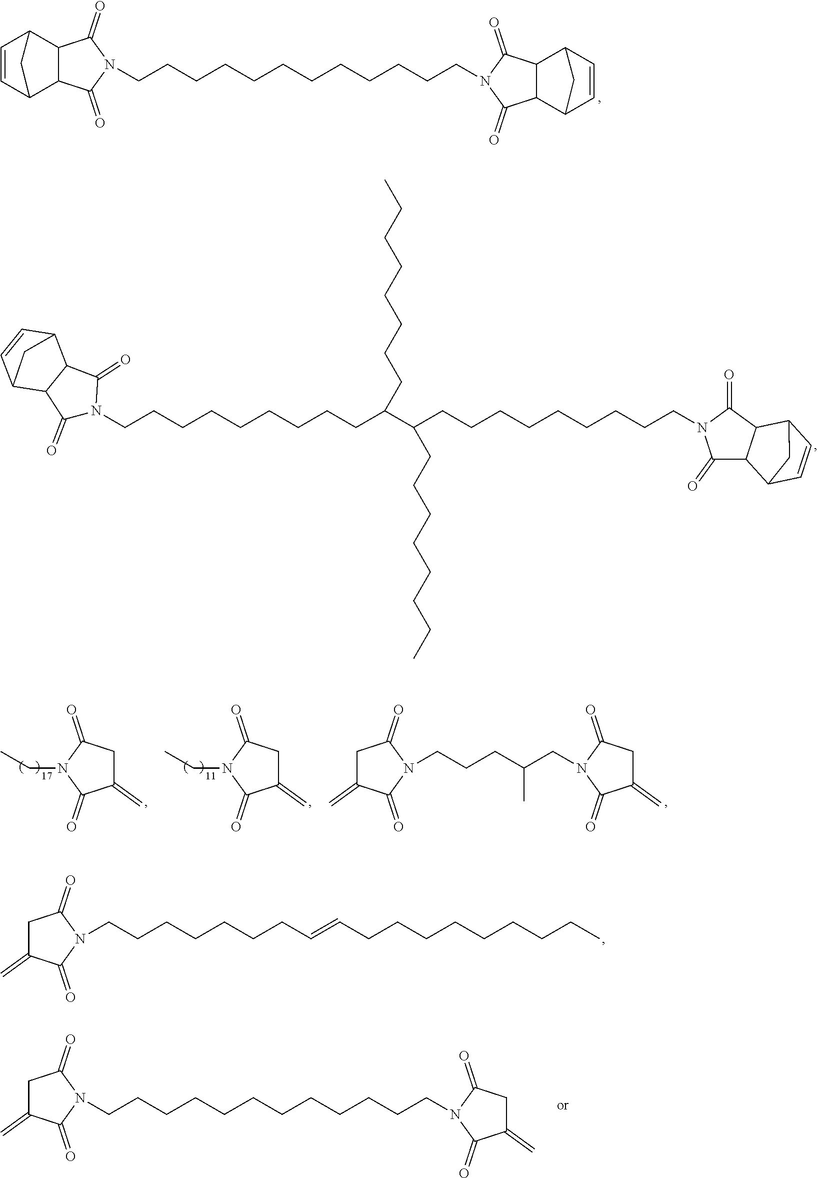

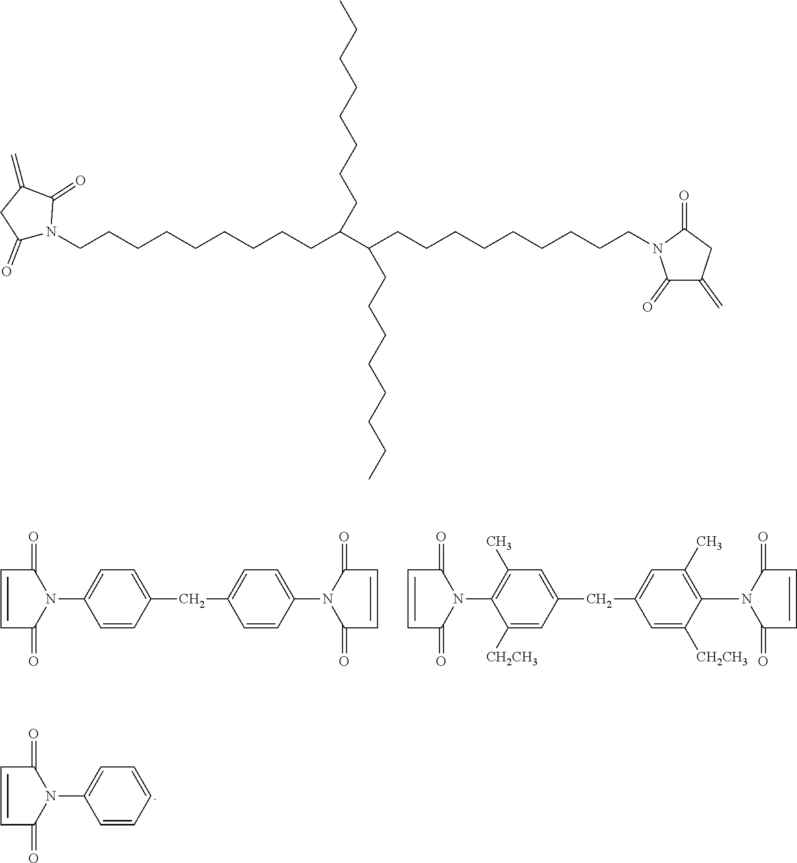

The thermosetting resin matrix should be present in an amount within the range of about 10 percent by weight to about 95 percent by weight, desirably about 20 percent by weight to about 80 percent by weight, such as about 60 percent by weight, based on the total weight of the thermosetting resin composition (less the silica filler and spinel crystal filler).

As a filler, silicas may be useful to modify the CTE between the semiconductor chip and the substrate to be mated and sealed so as to more closely match or modulate the CTEs of each. The silica filler influences the CTE and thus can be used to reduce thermal expansion of the cured material, thereby reducing warpage.

The silica filler may often include reinforcing silicas, such as fused spherical silicas, and may be untreated or treated so as to alter the chemical nature of their surface. The silica filler component should include particles having a mean particle size distribution in the 0.1 to 75 micron range, such as 0.1 to 50 micron range. A commercially available example of such particles is sold by Tatsumori or Denka in Japan. In addition, nano-size silica powder might be added, such as those sold under the tradename NANOPOX by Nanoresins, Germany. NANOPOX fillers are monodisperse silica filler dispersions in epoxy resins, at a level of up to about 50 percent by weight, available from Nanoresins, Germany. NANOPOX fillers ordinarily are believed to have a particle size of about 5 nm to about 80 nm.

Nanoresins also produces materials under the NANOPOX E trade designations. For instance, Nanoresins reports NANOPOX E-branded products enable the complete impregnation of electronic components which are difficult to seal otherwise and provide a large spectrum of mechanical and thermal properties such as reduced shrinkage and thermal expansion, fracture toughness and modulus. In the table below, Nanoresins-provided information on the four noted NANOPOX E products is set forth:

| | SiO₂ - | | | Dyn. Visc., |
|---|---|---|---|---|
| | Content | | EEW | 25° C. |
| Type | [wt %] | Base resin | [g/eq.] | [mPa · s] |
| NANOPOX | 40 | DGEBA/ | 290 | 45,000 |
| E 430 | | DGEBF | | |
| NANOPOX | 40 | DGEBA¹ | 295 | 60,000 |
| E 470 | | | | |
| NANOPOX | 40 | DGEBF² | 275 | 20,000 |
| E 500 | | | | |
| NANOPOX | 40 | EEC³ | 220 | 4,000 |
| E 600 | | | | |

¹diglycidyl ester of bisphenol
²diglycidyl ester of bisphenol
³3,4-epoxycyclohexylmethyl-3,4-epoxycyclohexylcarbonate

Nanoresins reports that important properties can be significantly improved in epoxy formulations by using NANOPOX E-brand products. For instance:

lower viscosity of the formulation in comparison to conventional reinforced fillers no sedimentation
increase in the fracture toughness, impact resistance and modulus
improved scratch and abrasion resistance
reduction of shrinkage and thermal expansion
improvement, or at least no negative effect, in numerous desired properties, such as thermal stability, chemical resistance, glass transition temperature, weathering resistance, and dielectric properties.

The processability is essentially unchanged in comparison to the respective base resin.

According to the manufacturer, NANOPOX E-branded products are a colloidal silica sol in an epoxy resin matrix. The dispersed phase consists according to the manufacturer of surface-modified, spherically shaped SiO₂ nanoparticles with diameters below 50 nm and an extremely narrow particle size distribution. These spheres, only a few nanometers in size, are distributed agglomerate-free in the resin matrix. This according to the manufacturer produces a very low viscosity of the dispersion with SiO₂ content of up to 40 percent by weight. As reported by the manufacturer, the nanoparticles are chemically synthesized from aqueous sodium silicate solution. In this process the binding agent is not damaged, in contrast to processes in which powdered fillers are dispersed with dissolvers or other equipment using high shear energy.

The silica filler should be present in an amount within the range of about 10 percent by weight to about 95 percent by weight, desirably about 20 percent by weight to about 80 percent by weight, such as about 60 percent by weight, based on the total weight of the thermosetting resin composition.

The inventive compositions also include spinel crystals.

The spinel crystals may be formed from one or more metal elements from the periodic table, such as cadmium, chromium, manganese, nickel, zinc, copper, cobalt, iron, magnesium, tin, gold, silver and titanium.

More specifically, the spinel crystals may be metal oxides of the types that are double oxides and found in AB₂O₄-type compounds or B (AB)O₄-type compounds where A and B are metal elements, such as those set forth above, desirably A may be copper.

The spinel crystals are ordinarily stable to elevated temperature conditions and are able to withstand acidic or alkaline conditions, such as those found in an aqueous metallization bath.

While the spinel crystals are dispersed substantially uniformly throughout the inventive compositions, some spinel crystals may be located on or near the surface of the cured reaction product so that when exposed to laser energy a predetermined pattern may be formed by the laser ablation and plating may occur according to the pattern.

A particularly desirable spinel crystal is available commercially from The Shephard Color Company under the trade designation LD-38 (described as a high performance copper chromite seed forming LDS additive, recommended by Shephard to be used in an amount of 1 to 8 percent by weight).

Here, while the spinel crystal may be used in the inventive compositions in an amount of about 1 to about 15 percent by weight, such as about 3 to about 12 percent by weight, desirably the spinel crystal should be used in the inventive composition in an amount of about 9 to about 10 percent by weight, based on the total weight of the thermosetting resin composition.

In this manner, and when desired, MIDs may be formed in a layer by layer process. More specifically, after the initial laser ablation is performed a fresh portion of thermosetting resin composition may be disposed thereover, subjected to elevated temperature conditions to form a cured reaction product, and then expose that or a different predetermined pattern to laser energy ablation may subsequently occur exposing a surface that is platable. This process may be repeated, for instance in as many times as desired by the end user, to create the three dimensional molded interconnect device sought.

The MID has a three dimensional circuit constructed on, in or about a molded device formed with the thermosetting resin composition described herein. For example, the three dimensional MID can include a molded article having a three dimensional structure, and a three-dimensional circuit formed on the surface of the molded article.

As noted above, a MID may be made using LDS, where a metal nucleus is produced on or about the surface of a cured reaction product of the thermosetting resin composition containing spinel crystals or an LDS additive.

Upon exposure to energy emitted by a laser, a metal nucleus may be formed from the spinel crystal as a seed and electroless plating may be used to form a predetermined plated pattern (e.g., wiring or circuitry) in a region having been exposed to the laser and an ablation formed according to that pattern.

The laser may be selected from lasers, such as YAG laser and excimer laser, and electron beams, of which the YAG laser is desirable. Further, the wavelength of the laser energy may be chosen, for example, in the range of 200 nm to 12,000 nm, desirably 248 nm, 308 nm, 355 nm, 532 nm, 1064 nm, 3,000 nm or 10,600 nm.

For instance, a 50-watt YAG laser may be employed to activate the surface of the cured reaction product by emitting energy at about 355, 532 of 1064 nm.

Generally, the laser can be modulated using an acousto-optic modulator/splitter/attenuator device to produce up to 23 watts in a single beam. The diameter of the laser beam may be at a focus distance of between any two of the following numbers, 1, 2, 4, 6, 8, 10, 15, 18, 20 or 25 microns, typically 18 or 12 microns. A typical exposure (or energy dose in J/cm²) may be between any two of the following numbers 0.1, 0.5, 1.0, 2, 4, 6, 8, 10, 15 or 20.

Plating may be accomplished after exposure to energy emitted by a laser through electroplating or electroless plating. By subjecting the region irradiated with laser to a plating treatment, a circuit can be formed through plating on that region.

Plating ordinarily uses a carrier liquid in which is dispersed (or in some instances dissolved) a metal component, such as one or more of copper, nickel, gold, silver, and palladium. The metal component may be present in a salt, chelate or complex form. The carried liquid may be any suitable liquid, such as water. For instance, the carrier liquid may be aqueous based forming a solution of 3.0 g/L copper (II), 9.0 g/L caustic acid, and 4.0 g/L formaldehyde.

The plating process may be conducted at a temperature of 55° C. for a period of time of about 60 minutes.

The cure component should be a latent one.

The cure component includes the combination of (1) a clathrate (such as a tetrakisphenol compound) and a (2) nitrogen-containing compound.

Examples of the clathrate as noted above include tetrakisphenol compounds, such as 1,1,2,2-tetrakis(4-hydroxyphenyl) ethane, 1,1,2,2-tetrakis(3-methyl-4-hydroxyphenyl) ethane, 1,1,2,2-tetrakis(3,5-dimethyl-4-hydroxyphenyl) ethane, 1,1,2,2-tetrakis(3-chloro-4-hydroxyphenyl) ethane, 1,1,2,2-tetrakis(3, S-dichloro-4-hydroxyphenyl) ethane, 1,1,2,2-tetrakis(3-bromo-4, hydroxyphenyl) ethane, 1,1,2,2-tetrakis(3,5-dibromo-4-hydroxyphenyl) ethane, 1,1,2,2-tetrakis(3-t-butyl-4-hydroxyphenyl) ethane, 1,1,2,2-tetrakis(3,5-di-t-butyl-4-hydroxyphenyl) ethane, 1,1,2,2-tetrakis(3-fluoro-4-hydroxyphenyl) ethane, 1,1,2,2-tetrakis(3,5-difluoro-4-hydroxyphenyl) ethane, 1,1,2,2-tetrakis(3-methoxy-4-hydroxyphenyl) ethane, 1,1,2,2-tetrakis(3,5-dimethoxy-4-hydroxyphenyl) ethane, 1,1,2,2-tetrakis(3-chloro-5-methyl-4-hydroxyphenyl) ethane, 1,1,2,2-tetrakis(3-bromo-5-methyl-4-hydroxyphenyl) ethane, 1,1,2,2-tetrakis(3-methoxy-5-methyl-4-hydroxyphenyl) ethane, 1,1,2,2-tetrakis(3-t-butyl-5-methyl-4-hydroxyphenyl) ethane, 1,1,2,2-tetrakis(3-chloro-5-bromo-4-hydroxyphenyl) ethane, 1,1,2,2-tetrakis(3-chloro-5-phenyl-4-hydroxyphenyl) ethane, 1,1,2,2-tetrakis [(4-hydroxy-3-phenyl)phenyl]ethane, 1,1,3,3-tetrakis(4-hydroxyphenyl) propane, 1,1,3,3-tetrakis(3-methyl-4-hydroxyphenyl) propane, 1,1,3,3-tetrakis(3,5-dimethyl-4-hydroxyphenyl) propane, 1,1,3,3-tetrakis(3-chloro-4-hydroxyphenyl) propane, 1,1,3,3-tetrakis(3,5-dichloro-4-hydroxyphenyl) propane, 1,1,3,3-tetrakis(3-bromo-4-hydroxyphenyl) propane, 1,1,3,3-tetrakis(3,5-dibromo-4-hydroxyphenyl) propane, 1,1,3,3-tetrakis(3-phenyl-4-hydroxyphenyl) propane, 1,1,3,3-tetrakis(3,5-diphenyl-4-hydroxyphenyl) propane, 1,1,3,3-tetrakis(3-methoxy-4-hydroxyphenyl) propane, 1,1,3,3-tetrakis(3,5-dimethoxy-4-hydroxyphenyl) propane, 1,1,3,3-tetrakis(3-t-butyl-4-hydroxyphenyl) propane, 1,1,3,3-tetrakis(3,5-di-t-butyl-4-hydroxyphenyl) propane, 1,1,4,4-tetrakis(4-hydroxyphenyl) butane, 1,1,4,4-tetrakis(3-methyl-4-hydroxyphenyl) butane, 1,1,4,4-tetrakis(3,5-dimethyl-4-hydroxyphenyl) butane, 1,1,4,4-tetrakis(3-chloro-4-hydroxyphenyl) butane, 1,1,4,4-tetrakis(3,5-dichloro-4-hydroxyphenyl) butane, 1,1,4,4-tetrakis(3-methoxy-4-hydroxyphenyl) butane, 1,1,4,4-tetrakis(3,5-dimethoxy-4-hydroxyphenyl) butane, 1,1,4,4-tetrakis(3-bromo-4-hydroxyphenyl) butane, 1,1,4,4-tetrakis(3,5-dibromo-4-hydroxyphenyl) butane, 1,1,4,4-tetrakis(3-t-butyl-4-hydroxyphenyl) butane, 1,1,4,4-tetrakis(3,5-di-t-butyl-4-hydroxyphenyl) butane and combinations thereof.

The nitrogen-containing compounds include amines, amides, and imidazoles, to name a few.

As amines, for examples, aliphatic amines, alicyclic and heterocyclic amines, aromatic amines, and modified amines may be used.

As aliphatic amines, some or all of ethylenediamine, trimethylenediamine, tetramethylenediamine, hexamethylenediamine, diethylenetriamine, triethylenetetramine, tetraethylenepentamine, dipropylenediamine, dimethylaminopropylamine, diethylaminopropylamine, trimethylhexamethylenediamine, pentanediamine, bis(2-dimethylaminoethyl) ether, pentamethyidiethylenetriamine, alkyl-t-monoamine, 1,4-diazabicyclo(2,2,2) octane (triethylenediamine), N,N,N′,N′-tetramethylhexamethylenediamine, N,N,N′,N′-tetramethylpropylenediamine, N, N, N′,N′-tetramethylethylenediamine, N, N-dimethylcyclohexylamine, dimethylaminoethoxyethoxy ethanol, dimethylaminohexanol and combinations thereof may be used.

As alicyclic and heterocyclic amines, some or all of piperidine, piperidine, menthanediamine, isophoronediamine, methylmorpholine, ethylmorpholine, N, N′,N″-tris(dimethylaminopropyl) hexahydro-s-triazine, 3,9-bis(3-aminopropyl)-2,4,8,10-tetraoxyspiro(5,5) undecaneadacto, N-aminoethylpiperadine, trimethylaminoethylpiperadine, bis(4-aminocyclohexyl) methane, N, N′-dimethylpiperadine, 1,8-diazabicyclo(4,5,0) undecene-7 and combinations thereof may be used.

As aromatic amines, o-phenylenediamine, m-phenylenediamine, p-phenylenediamine, diaminodiphenylmethane, diaminodiphenylsulfone, benzylmethylamine, dimethylbenzylamine, m-xylenediamine, pyridine, picoline and combinations thereof may be used.

As modified polyamines, polyamines added with epoxy compounds, polyamines added by Michael reaction, polyamines added by Mannich reaction, polyamines added with thiourea, ketone-blocked polyamines and combinations thereof may be used.

As imidazoles, some or all of imidazole and derivatives thereof, such as isoimidazole, imidazole, alkyl substituted imidazoles, such as 2-methyl imidazole, 2-ethyl-4-methylimidazole, 2,4-dimethylimidazole, butylimidazole, 2-heptadecenyl-4-methylimidazole, 2-methylimidazole, 2-undecenylimidazole, 1-vinyl-2-methylimidazole, 2-n-heptadecylimidazole, 2-undecylimidazole, 2-heptadecylimidazole, 2-phenylimidazole, 2-ethyl 4-methylimidazole, 1-benzyl-2-methylimidazole, 1-propyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-guanaminoethyl-2-methylimidazole and addition products of an imidazole methylimidazole and addition products of an imidazole and trimellitic acid, 2-n-heptadecyl-4-methylimidazole and the like, generally where each alkyl substituent contains up to about 17 carbon atoms and desirably up to about 6 carbon atoms; aryl substituted imidazoles, such as phenylimidazole, benzylimidazole, 2-methyl-4,5-diphenylimidazole, 2,3,5-triphenylimidazole, 2-styrylimidazole, 1-(dodecyl benzyl)-2-methylimidazole, 2-(2-hydroxyl-4-t-butylphenyl)-4,5-diphenylimidazole, 2-(2-methoxyphenyl)-4,5-diphenylimidazole, 2-(3-hydroxyphenyl)-4,5-diphenylimidazole, 2-(p-dimethylaminophenyl)-4,5-diphenylimidazole, 2-(2-hydroxyphenyl)-4,5-diphenylimidazole, di(4,5-diphenyl-2-imidazole)-benzene-1,4,2-naphthyl-4,5-diphenylimidazole, 1-benzyl-2-methylimidazole, 2-p-methoxystyrylimidazole, 2-phenyl-4,5-dihydroxymethylimidazole (commercially available under the tradename 2PHZ from Shikoku, Tokyo, Japan) and combinations thereof may be used.

Commercially available examples of the imidazoles include imidazole from Sigma-Aldrich Corporation, CUREZOL 1B2MZ (benzyl-2-methylimidazole) and CUREZOL 2P4MZ (2-phenyl-4-methylimidazole), each available commercially from Air Products and Chemicals Inc., and ARBADUR 9719-1 (2-ethyl-4-methylimidazole) from Huntsman Advanced Materials Americas Inc.

As amide compounds, polyamides obtainable by means of polymerization of dimaric acid and polyamine can be given, and as examples for ester compounds, active carbonyl compounds, such as aryl and thicaryl esters of carboxylic acids, may be used.

As other nitrogen containing compounds, dicyandiamide, guanidine, organic acid hydrazides, diaminomaleonitrile, amineimide, trifluoroboron-piperidine complex, trifluoroboron-monoethylamine complex and combinations thereof may be used.

The ratio of clathrate to nitrogen containing compounds should be about 2.5:1 to about 0.5:1, on a by mole basis.

Commercially available cure components include those from Nippon Soda under the tradename NISSOCURE.

The cure component should be included in an amount of about 0.1 percent by weight to about 20 percent by weight, such as about 2 percent by weight to about 12 percent by weight, based on the total resin composition.

A variety of additives may be included as illustrated in the examples below. Of particularly note, however, are the dispersants, such as those available commercially from BYK Chemie under the DYSPERBYK tradename.

A method for producing a molded electrically interconnected semiconductor device is also provided herein. The method includes steps which comprise:
Providing a wafer;
Dispensing onto at least a portion of a surface of the wafer a thermosetting resin composition in a flowable state at room temperature, as so-disclosed herein;
Exposing the wafer and the thermosetting resin composition to elevated temperature conditions suitable to cure the composition to form a reaction product on the wafer;
Exposing the so-formed reaction product to laser energy in a predetermined pattern to ablate the reaction product in that predetermined pattern and in so doing exposing a residue of the spinel crystal; and
Performing a plating over the predetermined pattern ablated in the cured reaction product.

In some embodiments the method may include:
Dispensing onto at least a portion of a surface of the reaction product of the cured thermosetting resin composition a further portion of the thermosetting resin composition;
Exposing the further portion of thermosetting resin composition to elevated temperature conditions suitable to cure the composition to form a reaction product;
Exposing the so-formed reaction product to laser energy in a predetermined pattern to ablate the reaction product in that predetermined pattern and in so doing exposing a residue of the spinel crystal; and
Performing a plating over the predetermined pattern ablated in the cured reaction product.

The method may be repeated multiple times to build a three dimensional molded electrically interconnected semiconductor device, according to a predetermined pattern.

Of course, a molded electrically interconnected semiconductor device is also provided. This device includes a wafer onto and/or about which is disposed an inventive thermosetting resin composition having been cured to a reaction product through exposure to elevated temperature conditions and having been exposed to laser energy in a predetermined pattern and having formed on that predetermined pattern metallization through plating.

The following examples are provided for solely illustrative purposes.

### EXAMPLES

A reconfigured wafer is ordinarily constructed today to have an 8″ or 12″ diameter. In use, the thermosetting resin composition used to encapsulate the wafer may be dispensed by air pressure or by piston dispense on or about a central portion of the wafer. Besides a reconfigured wafer, the inventive compositions may be molded onto a blank wafer and a trenched wafer as well.

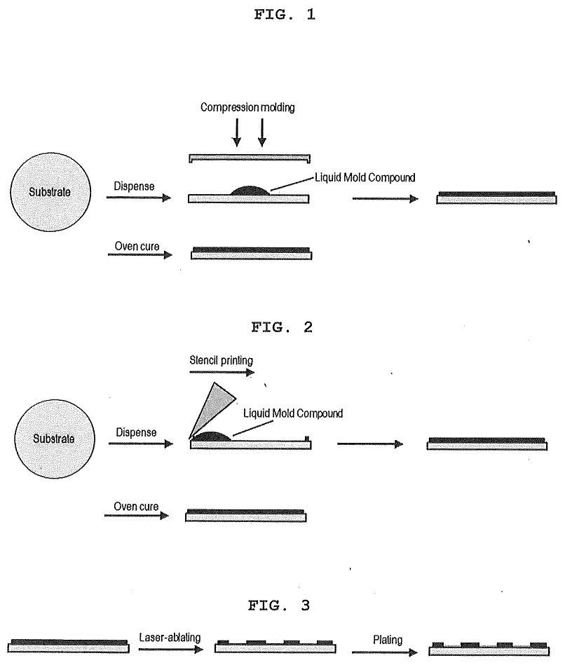

Exposure to liquid compression molding conditions, such as at a temperature of about 110° C. to 130° C. for a period of time of about 120 to 420 seconds, follows. See e.g. FIG. 1. After such exposure, the compression molded wafer may be placed into a conventional oven for a post mold cure at a temperature about 120° C. to less than about 150° C., such as at a temperature about 120° C. to about 130° C., for a period of time of about 15 minutes to 1 hour. Desirably, an 8″, 600 um thick molded wafer should demonstrate warpage of less than about 3 mm across of the wafer.

In a typical stencil printing process, Liquid Mold Compound is dispensed at room temperature to a substrate upon which a shim or stencil is used as a spacer. The Liquid Mold Compound is spread on the surface of the substrate by a metal squeegee to form a film layer. The thickness of the shim or stencil dictates the thickness of the resulting film layer on the substrate. See e.g. FIG. 2. After stencil printing, the stencil printed wafer may be placed into a conventional oven for a post mold cure at a temperature about 120° C. to less than about 150° C., such as at a temperature about 120° C. to about 130° C., for a period of time of about 15 minutes to 1 hour. Desirably, an 8″, 600 um thick molded wafer should demonstrate warpage of less than about 3 mm across of the wafer.

Control compositions (Sample Nos. 2 and 4) were prepared from a thermoset resin, silica filler, curative, and additives, including a coloring agent. In addition, two other compositions (Sample Nos. 1 and 3) were prepared in accordance with the present invention. The first two compositions were formulated for application as a Liquid Mold Compound in a printable encapsulant format (see FIG. 2); the second two compositions were formulated for liquid compression molding application (see FIG. 1). The compositions were evaluated for viscosity stability and were applied to a carrier on which is disposed silicon chips and molded as described above.

Warpage of the molded wafer can be measured by a Nikon NEXIV scanning system, or by using a Shadow Moirè in the X- and Y-directions, or by being estimated by a ruler as well.

The warpage of the molded wafer was measured after the molding and post-mold process.

Reference to Table 1 below shows the control compositions (Sample Nos. 2 and 4) and the inventive compositions (Sample Nos. 1 and 3) formulated with the noted components in the stated amounts.

TABLE 1

| Constituents | | Sample Nos./Amt (wt %) | | | |
|---|---|---|---|---|---|
| Type | Identity | 1 | 2 | 3 | 4 |
| Thermosetting | Bisphenol F Epoxy | 5.15 | 5.7 | 4.3 | 4.73 |
| Resin Matrix | Glycidyl ether epoxy | — | — | 0.9 | 1 |
| | Aliphatic epoxy | 2.2 | 2.4 | 1.5 | 1.65 |
| | Triglycidylized p- | 6.8 | 7.5 | 0.98 | 1.07 |
| | amino-phenol | | | | |
| Core Shell | Kane Ace MX 451 | 2.5 | 2.8 | 3.8 | 4.2 |
| Rubber | | | | | |
| Toughener | | | | | |
| Silica Filler | FB-310MDX | 68.25 | 75 | 64.38 | 70.7 |
| | SO-E2 | — | — | 11.19 | 12.3 |
| Spinel Crystal | Copper chromite | 9 | — | 9 | — |
| Curative | FUJICURE 1500 | 1.2 | 1.3 | — | — |
| | OMICURE 33DDS | 0.5 | 0.5 | — | — |
| | ADEKA EH 2110K | — | — | 0.8 | 0.9 |
| | ETHACURE 100 | — | — | 0.3 | 0.3 |
| Additives | Silane | 0.4 | 0.4 | 0.4 | 0.4 |
| | Carbon Black | 0.9 | 1 | 0.6 | 0.7 |
| | Defoamer | 0.1 | 0.1 | 0.05 | 0.05 |
| | Surfactant | 3 | 3.3 | 1.8 | 2 |

The compositions were each prepared by mixing together the noted constituents with a mechanical mixer until dissolution to a homogeneous solution was observed. The silica filler was then added with continued mixing for a period of time of about 30 to about 60 minutes at room temperature until a viscous paste with a substantially uniform consistency was achieved. The samples were then transferred into containers until ready for use.

The first two compositions were each dispensed onto and about the center of a silicon wafer as a carrier. After compression molding at a temperature of about 120° C. to less than about 130° C. for a period of time of about 200 seconds to about 400 seconds, the composition was observed to be about 60 to about 80% cured, though with a tack free surface. Then, the so-molded wafer was placed into a conventional oven for post mold cure at a temperature of about 120° C. to about 150° C. for a period of time of about 15 minutes to about 1 hour.

In their intended use, the inventive compositions in an LCM format may be dispensed onto the active side of a reconfigured wafer and molded under increased pressure (about 98 KN) and at an elevated temperature of about 110° C. to about 130° C. for a period about 3 minutes to about 7 minutes. The molded wafer assembly may then be exposed to an elevated temperature of about 130° C. to about 150° C. for a period of time of about 1 hour to about 2 hours. Desirably, with 200 um cured material, an 8″, 600 um thick silicon wafer should demonstrate warpage about less than about 3 cm, desirably less than about 2 cm, after post mold cure.

The molded wafer may be debonded, coated with a redistribution layer, solder bumps applied and thereafter diced into single semiconductor packages.

Reference to Table 2 below shows certain physical properties observed, including mechanical properties such as modulus and CTEs (α₁ or 1, and α₂ or 2), and measured after the samples were first exposed to compression molding conditions of a temperature of about 120° C. to less than about 130° C. for a period of time of about 200 seconds to about 400 seconds exposed for a further period of time of about 15 minutes to about 1 hour to a temperature of about 120° C. to about 150° C. in an oven.

TABLE 2

| | Sample Nos. | | | |
|---|---|---|---|---|
| Physical Properties | 1 | 2 | 3 | 4 |
| Warpage after oven cure (μm) | 383 | 424 | −48 | −34 |
| CTE 1, ppm/° C. | 11 | 14 | 9 | 9 |
| CTE 2, ppm/° C. | 33 | 31 | 22 | 21 |
| Storage modulus @ 25° C. (GPa) | 10.1 | 10.1 | 18.7 | 17.5 |
| DSC Onset/° C. | 134 | 134 | 133 | 133 |
| DSC Peak/° C. | 145 | 145 | 145 | 146 |
| DSC ΔH (J/g) | 99 | 114 | 68 | 87 |
| Viscosity 5 s − 1 (Pa · s) | 116 | 91 | 178 | 221 |
| Thixotropy index | 2.71 | 2.7 | 1.4 | 1.9 |
| Tg by TMA/° C. | 144 | 141 | 166 | 155 |
| Tg by DMA/° C. | 115 | 109 | 113 | 111 |

As shown in Table 2, the Liquid Mold Compound encapsulants with a spinel crystal filler additive (Sample Nos. 2 and 4) have similar physical properties as the control compositions (Sample Nos. 1 and 3). Put another way, the addition of spinel crystal filler has little impact on material application processing conditions, such as dispensing, printing, and spreading on substrates, and significantly as well as surprisingly, the properties of the resulting cured reaction product. Therefore, few, if any, changes to the composition may be desired for end use application here.

“Standard Test Method for Linear Thermal Expansion of Solid Materials by Thermomechanical Analysis,” ASTM International Designation: E831-06, published April 2006 (“E831-06”) describes a test method that “determines the apparent coefficient of linear thermal expansion of solid materials using thermomechanical analysis techniques.” See E831-06 at paragraph 1.1. This common method was used to measure CTE α₁ or 1.

“Standard Test Method for Plastics: Dynamic Mechanical Properties: In Flexure (Three-Point Bending),” ASTM International Designation: D 5023-01, published November 2001 (“D 5023-01”) discloses a test method that “is intended to provide means for determining the modulus as a function of temperature for a wide variety of plastics materials.” See D 5023-01 at paragraph 1.2, emphasis added. This common method was used to measure storage modulus.

To achieve high Tg and low warpage on flip chip semiconductor packaging, low temperature curing conditions (below about 130° C.), with compositions that exhibit fast gellation after exposure to such low temperature curing conditions have been shown to influence warpage. The Tg of the cured composition should be equal to or higher than the temperature used to cure the composition; the Tg should be higher than 90° C., desirably above 125° C. If the composition cures slowly or at a higher temperature, the stress free point between the die and substrate set is high. Warpage at room temperature results from cooling the compression molded semiconductor package to room temperature from the cure temperature.

To achieve high reliability for thermal cycle performance between −55° C. to 125° C. of such compression molded semiconductor packages, the liquid compression molding material should have Tg by TMA after reflow at 260° C. above 90° C. and desirably above 125° C., a DSC peak below 140° C., a delta temperature between the onset and the peak on DSC below 20° C.

The inventive compositions achieve the following properties, when cured:
a) Storage modulus in the range of 25 GPas or less at room temperature (25° C.), measured by DMA (3-point bending method, at 5° C./min),
b) CTE al of less than or equal to 15 ppm/° C., and a CTE α2 of less than or equal to 30 ppm, measured by TMA (at ramp rate of 5° C./min),
c) At least one Tg above 135° C., measured by TMA (3-point bending method, at ramp rate of 5° C./min).

As shown in FIG. 3, the cured reaction product may be laser-activated by laser ablating to influence the spinel crystals to aggregate and become exposed at the surface so that they may be platable.

Table 3 below shows some data observed and collected on plating performance of LDS materials illustrated by Sample Nos. 1 and 3 compared with Pocan reference. Samples No. 1 and 3 were applied and cured onto silicon wafer substrates, such as is depicted in FIGS. 2 and 1, respectively. Each of the cured Sample Nos. 1 and 2, and the Pocan Reference were evaluated using the same process of laser ablation and plating as depicted in FIG. 3. The Pocan Reference is a commercial thermoplastic material containing spinel crystal filler which is used as a reference.

TABLE 3

| LDS Formulation | Sample No. 1 | | | Sample No. 3 |
|---|---|---|---|---|
| Application Method | Stencil Printing | | | Liquid Compression |
| | | | | Molding |
| Coating Layer (μm) | 100 | 75 | 50 | 200 |
| Mean(μm) | 2.42 | 2.29 | 2.27 | 2.65 |
| Std Dev (μm) | 0.52 | 0.43 | 0.58 | 0.37 |
| Pocan | 3.38 | | | 3.00 |
| Reference*(μm) | | | | |
| Mean Plating Index** | 0.72 | 0.68 | 0.67 | 0.88 |

*Plating thickness
**Ratio of Mean Copper Thickness to Pocan Reference

The Mean Plating Index is indicative of the degree to which the laser ablated cured reaction product may be plated compared with the commercially available thermoplastic LDS material used as a control. Generally, the higher the Mean Plating Index value, the better is the platability.

What is claimed is:

1. A thermosetting resin composition in a flowable state at room temperature, comprising:
a thermosetting resin matrix,
a silica filler,
spinel crystals, and
a cure component comprising the combination of a clathrate comprising the combination of a tetrakis phenol compound and a nitrogen-containing curative, wherein when disposed on at least a portion of a substrate and cured to a non-flowable state on or about the portion of the substrate after exposure to elevated temperature conditions, the cured composition is platable upon exposure to laser energy and the substrate on which the cured composition is disposed on or about exhibits a warpage of less than about 3 cm.

2. The composition according to claim 1, wherein when cured the composition has at least one of the following physical properties:
(a) storage modulus in the range of about 25 GPas or less at room temperature,
(b) a CTE α1 of less than or equal to 20 ppm/° C.,
(c) a CTE α2 of less than or equal to 40 ppm/° C.

3. The composition according to claim 1, wherein the substrate is a wafer constructed of silicon and the composition is disposed on or about the wafer at a thickness of less than about 50 percent of the thickness of the wafer.

4. The composition according to claim 1, wherein the spinel crystals are formed from metals selected from one or more of cadmium, chromium, manganese, nickel, zinc, copper, cobalt, iron, magnesium, tin, gold, silver and titanium.

5. A method of improving warpage resistance of An encapsulated molded wafer, steps of which comprise:
Providing a wafer;
Providing a thermosetting resin composition according to claim 1 in contact with the wafer; and
Exposing the wafer and the thermosetting resin composition to conditions favorable to allow the thermosetting resin composition to flow about the wafer and cure to reaction product of the thermosetting resin composition which is capable of improving warpage resistance by about 50 percent or greater.

6. The method according to claim 5, wherein the warpage resistance is improved by about 65 percent or greater.

7. The method according to claim 5, wherein the warpage resistance is improved by about 80 percent greater.

8. A product formed from the method of claim 5.

9. The composition of claim 1, wherein the thermosetting resin component comprises an epoxy resin, an episulfide resin, an oxazine, an oxazoline, a cyanate ester, and/or a maleimide-, a nadimide- or an itaconimide-containing component.

10. A method for producing a molded electrically interconnected semiconductor device, steps of which comprise:
A. Providing a substrate;
B. Dispensing onto at least a portion of a surface of the substrate a thermosetting resin composition in a flowable state at room temperature according to claim 1;
C. Exposing the substrate and the thermosetting resin composition to elevated temperature conditions suitable to cure the composition to form a reaction product on the substrate;
D. Exposing the so-formed reaction product to laser energy in a predetermined pattern to ablate the reaction product in that predetermined pattern and in so doing exposing a residue of the spinel crystal; and
E. Performing a plating over the predetermined pattern ablated in the cured reaction product.

11. The method according to claim 10, further comprising:
F. Dispensing onto at least a portion of a surface of the reaction product of the cured thermosetting resin composition from step C a further portion of the thermosetting resin composition;
G. Exposing the further portion of thermosetting resin composition to elevated temperature conditions suitable to cure the composition to form a reaction product;
H. Exposing the so-formed reaction product to laser energy in a predetermined pattern to ablate the reaction product in that predetermined pattern and in so doing exposing a residue of the spinel crystal; and
I. Performing a plating over the predetermined pattern ablated in the cured reaction product.

12. The method according to claim 10, further comprising:
Repeating steps F-I.

13. A three dimensional molded electrically interconnected semiconductor device from the method of claim 10.

14. A molded electrically interconnected semiconductor device comprising:
A substrate;
A thermosetting resin composition having been cured to a reaction product through exposure to elevated temperature conditions and having been exposed to laser energy in a predetermined pattern and having formed on that predetermined pattern metallization through plating disposed on or about the substrate.
